(19) United States
(12) Patent Application Publication
(10) Pub. No.: US 2013/0010428 A1
(43) Pub. Date: Jan. 10, 2013

(54) FIXING SPRING AND HEAT SINK STRUCTURE FOR ELECTRONIC COMPONENT

(75) Inventor: Kiyoshi HAYASHI, Tokyo (JP)

(73) Assignee: TDK Corporation, Tokyo (JP)

(21) Appl. No.: 13/541,961

(22) Filed: Jul. 5, 2012

(30) Foreign Application Priority Data
Jul. 8, 2011 (JP) 2011-152274

(51) Int. Cl. H05K 7/14; H05K 7/20

(52) U.S. Cl. 361/704; 248/224.8; 248/205.1

(57) ABSTRACT

A fixing spring for fixing an electronic component to a heat sink member includes a seat part that extends in a horizontal direction, a holding part that is provided to extend from one of two first sides of the seat part that face each other toward the horizontal direction of the first sides and that presses the electronic component onto the heat sink member, a leg part that is provided to extend substantially perpendicularly downwardly from one of two second sides of the seat part that face each other, a leg part body that extends from the leg part, and a claw part that is provided at a tip end of the leg body. The holding part biases the electronic component downwardly and thereby fixes the electronic component on the heat sink member when the claw part is engaged with the engagement hole.

### CROSS REFERENCE TO RELATED APPLICATION

The present application is related to, claims priority from and incorporates by reference Japanese patent application No. 2011-152274, filed on Jul. 8, 2011.

### TECHNICAL FIELD

This invention relates to a fixture for fixing electronic components, which are semiconductors and the like that are mounted on an electronic device, to a heat sink member, the electronic components, such as a transistor, a diode and the like, generating a large amount of heat.

### BACKGROUND

A fixture that holds an electronic component is used as a fixture for fixing an electronic component, such as semiconductor, mounted on an electronic device, to a heat sink member. Such a fixture is disclosed in JP Laid-Open Utility Model Application No. H5-46086 and JP Laid-Open Patent Application No. H9-293981, for example.

JP Laid-Open Utility Model Application No. H5-46086 discloses an invention for fixing an electronic component on a heat sink plate by using a holder. The holder is formed by a seat on which an attachment hole is provided, and a pair of approximately L-shape restraining pieces extending from both sides of the seat. The restraining pieces are formed by inclining from a base part of the restraining pieces downwardly toward a tip end. In addition, a tip part of a rotation regulation piece formed by extending from a front surface part of the seat is folded downwardly to form a folding part. In order to fix an electronic component on a heat sink plate by using the above configured holder, the holder is placed over the electronic component from the upper side of the electronic component. At this time, a screw hole of the seat and the attachment hole are aligned by engaging the folding part of the rotation regulation piece with an edge of the heat sink plate. A screw is inserted into the attachment hole from the lower side of the heat sink plate and then screwed in the screw hole. After attaching the holder to the heat sink plate, the holder is secured because the holding part of the rotation regulation piece engages with the edge of the heat sink plate. In addition, the restraining pieces, of which tips incline downwardly, become horizontal as the restraining pieces press the surface of the electronic component. Furthermore, the electronic component is fixed by being closely attached to the heat sink plate as a downward spring back force is generated, resulting in an even force being applied to the entire body of the electronic component.

JP Laid-Open Patent Application No. H9-293981 discloses a fixing device for an electronic component. The fixing device is configured with a board, a heat sink body that is formed of a heat conductive material and that protrudes from at least one side surface of the board, an electronic component provided on the side surface of the board and connected to a wiring pattern, and a fixing means for heat-conductively fixing the electronic component to the heat sink body.

JP Laid-Open Patent Application No. H9-293981 discloses a clamp 11 as fixing means for a transistor. The clamp 11 is formed from an elastic material, such as synthetic resin, in an approximately F shape. An arm 12, which is formed in the clamp 11, is provided in parallel with a side wall 1A of a casing 1. In the middle of the arm 12, a shaft 13 is formed to protrude perpendicularly toward the side wall 1A. On the tip end side of the arm 12, an engaging part 15 protrudes to the outer surface of the casing 1 through an insertion hole 14 provided in the side wall 1A. On both end sides of the arm 12, a pinching part 16 and a pinch reinforcing part 17 are formed sandwiching the shaft 13.

However, in JP Laid-Open Utility Model Application No. H5-46086, when the holder is used, a step between the part (seat) that is closely attached and fixed on the heat sink plate, and restraining pieces that hold the electronic component differs depending on a thickness of the electronic component used. Therefore, a difference in height needs to be adjusted in accordance with the thicknesses of electronic components due to various electronic components used for each process or due to a difference in the thickness of the electronic components caused by manufacturing errors. In addition, when the holder is fixed by a screw, there may be drawbacks in precision at the time of creating a screw hole, a possibility of cracking at the time of tightening the screw during assembly, and loosening of the screw after the assembly.

Moreover, in JP Laid-Open Patent Application No. H9-293981, because the clamp 11 has an approximately F shape, which is unique, its production is not easy. In addition, a single clamp can only fix a single transistor. Furthermore, the fixture needs to be separately designed for transistors with various heights because a height of the pinch reinforcing part 17 is constant.

Therefore, one of objects of the present invention is to provide a fixing spring tool for a semiconductor and the like, which is capable of easily attaching an electronic component to a heat sink member by forming a fastener at a tip part of the fixture, and through insertion of the fastener formed on the fixture into a hole formed on the heat sink member at the time of attaching the electronic component to the heat sink member. As a result, the number of components is reduced and drawbacks associated with screw-clamping are resolved.

### SUMMARY

A fixing spring of the present invention for fixing an electronic component to a heat sink member that includes a flat surface on which the electronic component is disposed by inserting the fixing spring to an engagement hole disposed on the flat surface of the heat sink member, including: a seat part that extends in a horizontal direction; a holding part that is provided to extend from one of two first sides of the seat part that face each other toward the horizontal direction of the first sides and that presses the electronic component onto the heat sink member; a leg part that is provided to extend substantially perpendicularly downwardly from one of two second sides of the seat part that face each other; a leg part body that extends from the leg part; and a claw part that is provided at a tip end of the leg body. Wherein the holding part biases the electronic component downwardly and thereby fixes the electronic component to the heat sink member when the claw part is engaged with the engagement hole.

In another view of the present invention, a distance between the holding part and the heat sink member, which is defined where the fixing spring is fixed to the heat sink member not having the electronic component therebetween, is smaller than a height of the electronic component.

In another view of the present invention, the leg part provided at the seat part is comprised with first and second leg parts that are respectively arranged on the second sides of the seat part, and the leg part body that expends from the leg part is comprised with first and second leg part bodies that are provided with each of the first and second leg parts.

In another view of the present invention, the leg part provided at the seat part is comprised with first and second leg parts that are respectively arranged on the second sides of the seat part, and the leg part body is a single leg body, being provided with each of the first and second leg parts.

In another view of the present invention, the claw part is provided at a tip end of the first leg part body, and another claw part is provided at a tip end of the second leg part body, thereby a pair of the claw parts is formed, and the pair of the claw parts engages with the engagement hole.

In another view of the present invention, a fixing part is provided at a tip end of the holding part to make a surface contact with the electronic component and to fix the electronic component.

In another view of the present invention, a plurality of third claw parts are provided on the leg part body, allowing an engagement position of the fixing spring and the heat sink member to vary.

In another view of the present invention, the claw part is formed by the tip end part of the leg part body being folded, and an engagement position between the fixing spring and the heat sink member varies based on a position at which the tip end part of the leg part body is folded.

According to the present invention, by inserting an engagement claw provided on a fixing spring into an engagement hole provided on the heat sink member, an electronic component is sandwiched and fixed to a heat sink member. Accordingly, the positioning is simplified.

In addition, because the only assembly process after the positioning is the fitting of the engagement claw, there is no cracking or warping of components caused by screw-clamping. Therefore, the assembly process and operation process are simplified, resulting in improved efficiency.

Moreover, a structure of the fixing spring is simple. Therefore, complicated manufacturing processes are not required. As a result, the manufacturing processes are simplified. This is advantageous for mass production. Further, because screws and the like are not used, the number of parts is reduced, resulting in simplified manufacturing processes.

In addition, a plurality of electronic components can be engaged with the heat sink member with a single fixing spring. The number of electronic components to be fixed to the heat sink member is adjusted by changing the number of leg parts of the fixing spring.

Furthermore, because the electronic component contacts the heat sink member and because the leg part of the fixing spring contacts the heat sink member, even if excess pressure is accidentally applied to the fixing spring, the pressure is dispersed to the leg part and the electronic component. As a result, excess pressure is not applied to the electronic component, resulting in preventing damage to the electronic component.

### BRIEF DESCRIPTION OF THE DRAWINGS

FIG. 1 is an exploded perspective view of a first embodiment according to the present invention.

FIG. 2 is a perspective view of the first embodiment according to the present invention.

FIG. 3 illustrates an insertion state of a fixing spring and an engagement hole of the first embodiment according to the present invention.

FIG. 4 is a side view of the first embodiment according to the present invention.

FIG. 5A is a perspective view of the fixing spring of the first embodiment according to the present invention. FIG. 5B is a perspective of the fixing spring shown in FIG. 5A viewed from a back surface.

FIG. 6 is an exploded perspective view of a second embodiment according to the present invention.

FIG. 7 is a side view of the second embodiment according to the present invention.

FIG. 8A is a perspective view of the fixing spring of the second embodiment according to the present invention. FIG. 8B is a back surface perspective of the fixing spring shown in FIG. 8A.

FIG. 9A is a side view of a third embodiment according to the present invention. FIG. 9B is a side view of a fourth embodiment according to the present invention.

FIG. 10A is a perspective view of a heat sink member of an embodiment according to the present invention. FIG. 10B is a perspective view the heat sink member of another embodiment of according to the present invention.

### DETAILED DESCRIPTION OF EMBODIMENTS

In the disclosure of the present application, terms describing relative directions, such as horizontal or vertical, are used. Such terms are used to enhance the understanding of the disclosure and are not intended to indicate the specific directions to enable the disclosure. In addition, the term “vertical” is a synonym for the term “perpendicular.”

### First Embodiment

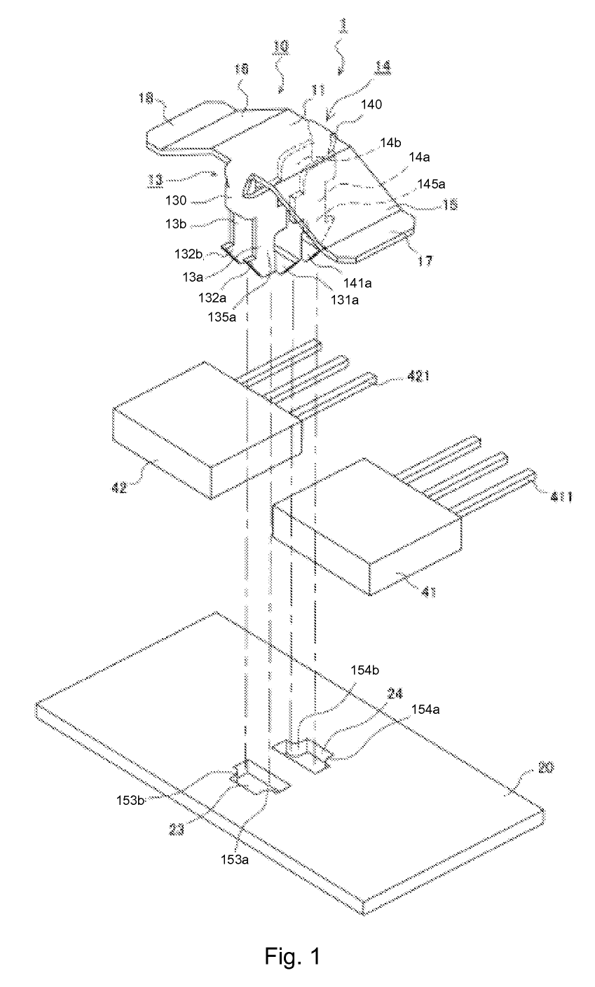

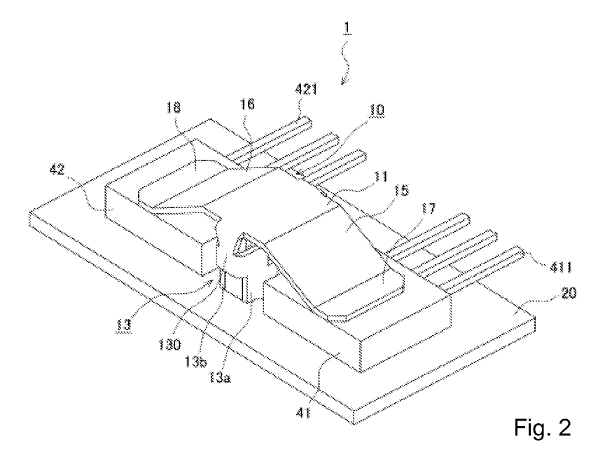

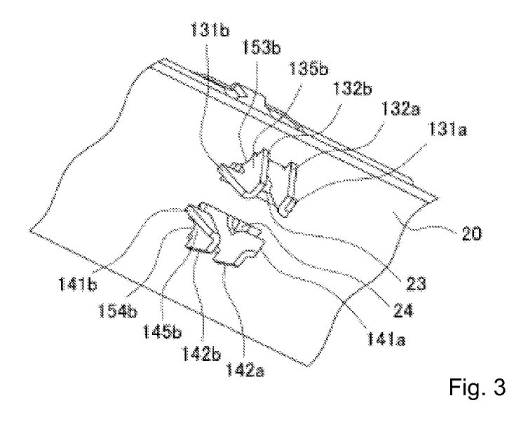

A first embodiment of the present invention is explained using FIGS. 1 to 5.

[Configuration of Heat Sink Structure]

A heat sink structure 1 shown in FIGS. 1 to 5 is for efficiently dissipating heat generated by an electronic component and achieves close attachment (fixing) of the electronic component used for a circuit board of an electric device, such as a power source device, to a heat sink member. The heat sink structure 1 is configured with a fixing spring 10, a heat sink member 20 and electronic components 41 and 42 provided on the heat sink member 20.

The electronic components 41 and 42 are electronic components, such as transistors and diodes. The electronic components 41 and 42 include terminals 411 and 421. The terminals 411 and 421 are electrically connected to the circuit board by soldering and the like. The electronic components 41 and 42 perform operation and generate a large amount of heat as voltage is applied. A temperature of the electronic components 41 and 42 needs to be decreased by providing a heat sink device because the performance thereof is reduced by the temperature increase. To efficiently dissipate the heat in a short period, in general, it is preferable to increase a contact area between electronic components and heat sink devices so that heat conduction efficiency increases. Therefore, it is necessary that bottom surfaces (first surface) of the electronic components 41 and 42 be closely attached to the heat sink member 20. The electronic components 41 and 42 also include top surfaces (second surface) in addition to the bottom surface.

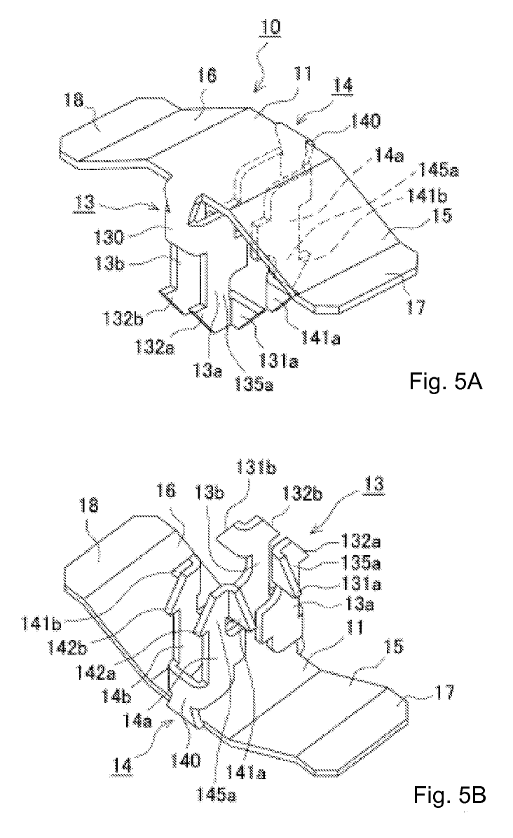

As shown in FIG. 5, the fixing spring 10 includes a rectangular seat part 11 that spreads in a horizontal direction (direction substantially parallel with the heat sink member 20), and leg parts 13 and 14 (first and second leg parts) provided so as to extend vertically (perpendicularly) downwardly (the heat sink member 20 side) from opposing two sides of the seat part 11. The two sides from which the leg parts 13 and 14 extend are defined second sides. Through the disclosure of the application, the terms, vertical, perpendicular and parallel include substantial meanings. For example, in a case of “perpendicularly,” the term means 90 degrees and some degrees in the light of technical common sense. The number of leg parts may be at least one or more in order to engage (position) the fixing spring 10 with the heat sink member 20. The first embodiment according to the present invention illustrates an example in which the leg parts 13 and 14, respectively includes two leg part bodies 13a and 13b (first and second leg part bodies), and 14a and 14b (first and second leg part bodies).

The leg part 13 (14) is configured with a stand part 130 (140) that is connected to the seat part 11, the leg part bodies 13a and 13b (14a and 14b) that are connected to the stand part and that extend in a direction opposite from the seat part 11, and engagement claws (first claw part) 131a and 131b (141a and 141b) provided at the respective tip ends of the leg part bodies 13a and 13b (14a and 14b).

The stand part 130 (140) is provided to extend vertically downwardly (the heat sink member 20 side) from opposing two sides of the seat part 11. The leg part bodies 13a and 13b (14a and 14b) are respectively provided from the left and right end parts of the stand part 130 (140).

The leg part bodies 13a and 13b (14a and 14b) are provided to extend vertically downwardly (the heat sink member 20 side) from the left and right end parts of the stand part 130 (140). Further, the leg part bodies 13a and 13b (14a and 14b) are formed by perpendicularly bending in a direction parallel with borderlines between the seat part 11 and holding parts 15 and 16 (a direction orthogonal to the stand parts 130 and 140). In addition, the leg part bodies 13a and 13b, and the leg part bodies 14a and 14b are respectively folded in parallel with each other. Moreover, all of the leg part bodies have plate like shapes, and the leg part bodies 13a and 14a are positioned substantially coplanarly. The leg part bodies 13b and 14b are also positioned substantially coplanarly.

The engagement claws 131a and 131b (141a and 141b) are provided at tip end parts of the leg part bodies 13a and 13b (14a and 14b) and are bent in a direction orthogonal to the leg part bodies 13a and 13b (14a and 14b) (direction parallel with the stand part 130 and 140). Small claws (second claw part) 132a and 132b (142a and 142b) are provided at the leg part bodies 13a and 13b (14a and 14b) in a direction opposite from the engagement claws 131a and 131b (141a and 141b).

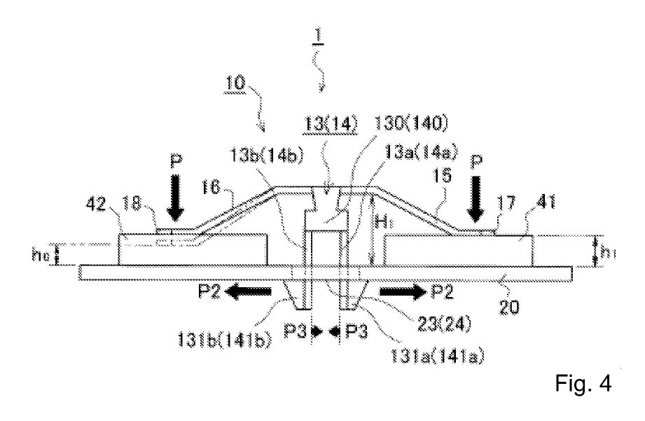

The holding parts 15 and 16 are provided to extend horizontally (side directions), or more specifically, in a diagonally downward direction with respect to the horizontal direction, from two sides of the seat part 11 with the same width as the seat part 11, to press the electronic components 41 and 42 toward the heat sink member 20 side. Fixing parts 17 and 18 are respectively provided from tip ends of the holding parts 15 and 16. The two sides with which the holding parts 15 and 16 are provided are defined first sides of the seat part 11. An inclination angle of the holding parts 15 and 16 in the diagonally downward direction may be in any range between 0 degrees and 90 degrees depending on a height relationship of the electronic components 41 and 42 to be fixed, materials of the holding parts 15 and 16, and the like. Because a height position h0 of the holding parts 15 and 16 at the time of assembling the fixing spring 10 and the heat sink member 20 is lower than a height h1 of the electronic components 41 and 42, the electronic components 41 and 42 are biased downwardly when the holding parts 15 and 16 are curved by the electronic components 41 and 42 (see P shown in FIG. 4). The biasing force is generated due to an elastic feature of the holding parts or an elastic feature of joining section between the seat part the holding part. Therefore, even with the electronic components 41 and 42 with slightly different height h1, the holding parts 15 and 16 fix the electronic components 41 and 42 to the heat sink member 20 by the above-described biasing. In the drawings, the holding parts 15 and 16 are illustrated in plate shapes. However, it is also practical to form the holding part in a generally downwardly curved shape as long as it generates the biasing force toward the electronic component. Further, two of the holding parts do not necessarily have to be in the identical shape.

The fixing parts 17 and 18 closely attach the electronic components 41 and 42 and press-fix the electronic components 41 and 42 by contacting the electronic components 41 and 42 on a surface of the heat sink member 20. Therefore, to secure sufficient contact with the electronic components 41 and 42, the fixing parts 17 and 18 are formed by being bent in the horizontal direction in correspondence with shapes of the electronic components 41 and 42 in the present embodiment. As a result, surface contacts are secured between the fixing parts 17 and 18 and the electronic components 41 and 42, respectively. In addition, if the electronic components 41 and 42 can be sufficiently contacted with the heat sink member 20, the electronic components may be press-fixed by the tip end parts of the holding parts 15 and 16 without the fixing parts 17 and 18.

When the heat sink member 20 and the fixing spring 10 are engaged, the holding parts 15 and 16 function as elastic members with the center of the seat part 11 as a center of gravity, and the fixing parts 17 and 18 at the respective tip end parts of the holding parts 15 and 16 function to press the electronic components 41 and 42 in the downward direction (indicted by arrows P in FIG. 4) and to make the close surface-contact and to fix the heat sink member 20 and the electronic components 41 and 42.

The material of the fixing spring 10 may be, but are not limited to, a metal plate, a resin plate and the like that can be processed as a fixing plate. In view of a feature of generating a biasing force, the material for the fixing spring 10 is preferably elastic. Moreover, in case of a metal plate, manufacturing is simple because the metal plate can be produced by press-working a sheet of metal.

The heat sink member 20 is configured to include a flat surface to closely attach to (contact) the electronic components 41 and 42 in order to secure the close attachment and fixture with the electronic components 41 and 42. Further, the heat sink member 20 has a function to dissipate the heat generated by the electronic components arranged on the heat sink member 20. For the material of the heat sink member 20, a metal with good heat conductivity for heat dissipation, such as aluminum, copper and the like, may preferably be used. On the heat sink member 20, engagement holes 23 and 24 are provided for engaging with the engagement claws 131a, 131b, 141a and 141b of the fixing spring 10.

The engagement hole 23 (24) is provided on the heat sink member 20. The engagement claws 131a and 131b (141a and 141b) engage edges of the engagement hole 23 (24). To prevent backlash, two or more engagement claws preferably engage with one engagement hole. A shape of the engagement hole 23 (24) is formed in a T-shape with a wide area in a position where the leg part 13 (14) is inserted, and narrow areas that include engagement hole contact parts 153a and 153b (154a and 154b) at which the engagement claws 131a and 131b (141a and 141b) are positioned.

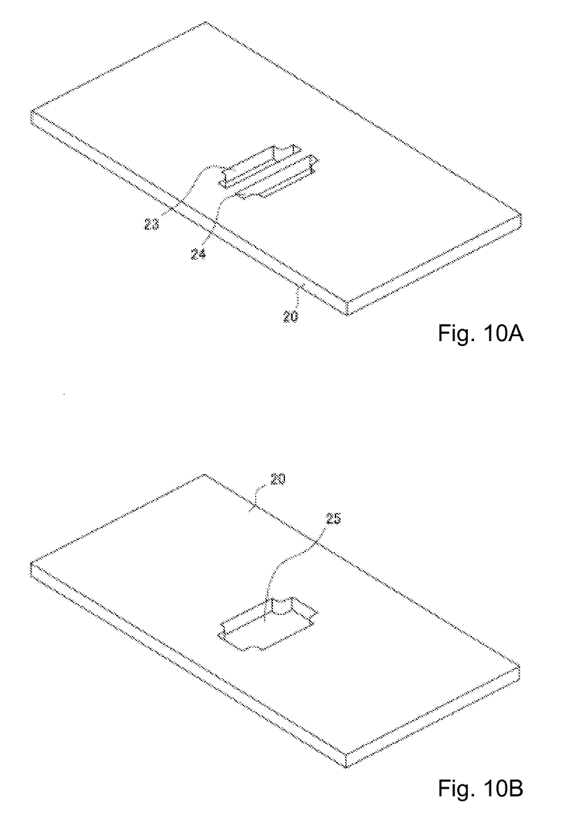

The shape of the engagement holes 23 and 24 is not limited to the T-shape but may be rectangular, oval or circular, for example, as long as the engagement claws engage and backlash does not occur. Moreover, when the engagement hole is engaged by two engagement claws, two engagement holes (23, 24) may be provided in parallel with each other along the longitudinal direction of the heat sink member 20 (see FIG. 1). Alternatively, two engagement holes may be provided in parallel with each other in a direction perpendicular to the longitudinal direction of the heat sink member 20 (see FIG. 10A). Yet alternatively, the area of an engagement hole may be increased, and four engagement claws may be engaged with a single engagement hole 25 (see FIG. 10B). In this case, the shape of the engagement hole 25 may be rectangular, oval or circular, for example, as long as the engagement claws engage and as the backlash does not occur.

[Assembly Method of Heat Sink Structure]

Steps for fixing electronic components by using the fixing spring 10 are explained with reference to FIGS. 1 to 4.

First, the electronic components 41 and 42 are mounted on a top surface of the heat sink member 20. An insulation sheet (not shown) may be sandwiched between the heat sink member 20 and the electronic components 41 and 42.

Next, the fixing spring 10 and the heat sink member 20 are fitted to each other. The tip end parts of the engagement claws 131a and 131b at the tip end of the leg part 13 and the tip end pars of the engagement claws 141a and 141b at the tip end of the leg part 14 are respectively inserted into the engagement holes 23 and 24. At that time, the engagement claws 131a, 131b, 141a and 141b are inserted into the wider parts of the T-shape engagement holes 23 and 24.

Here, in case of fitting the leg parts 13a and 13b in the engagement hole 23, the leg parts 13a and 13b are momentarily depressed in directions of P3, and are deformed by edge parts of the engagement hole 23, as shown in FIG. 4. Then, as the leg parts 13a and 13b (14a and 14b) are fitted in the engagement hole 23 and are provided at positions where leg part contact parts 135a and 135b (145a and 145b) and engagement hole contact parts 153a and 153b (154a and 154b) contact each other, the depressions in the P3 directions are released, and the leg parts 13a and 13b (14a and 14b) are biased in the outer direction (directions of P2) due to the elastic force of the leg parts 13a and 13b (14a and 14b). As a result, the leg part contact parts 135a and 135b (145a and 145b) and the engagement hole contact parts 153a and 153b (154a and 154b) are respectively pressed against, and fixed to, each other. Further, the engagement claws 131a and 131b (141a and 141b) and the small claws 132a and 132b (142a and 142b) protrude over the edge parts of the engagement hole 23 (24). Therefore, the fixing spring 10 engages and is fixed to the heat sink member 20 without disengagement.

Moreover, effect of pressure becomes more significant by making the shape of the leg part contact parts 135a, 135b, 145a and 145b match the shape of the engagement hole contact parts 153a, 153b, 154a and 154b. Therefore, backlash is further prevented.

At that time, the fixing parts 17 and 18 are respectively positioned such that the fixing part 17 contacts the upper surface of the electronic component 41 and that the fixing part 17 contacts the upper surface of the electronic component 42. In addition, the leg parts 13 and 14 contact the heat sink member 20. The pressure from the fixing spring 10 is dispersed. As a result, the fixing parts 17 and 18 do not apply the excess pressure on the electronic components 41 and 42, resulting in preventing damage to the electronic component.

### Second Embodiment

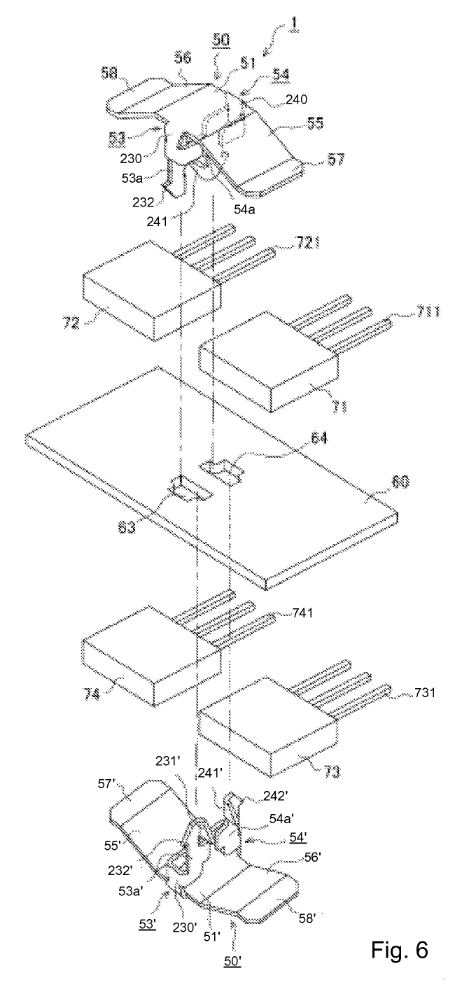

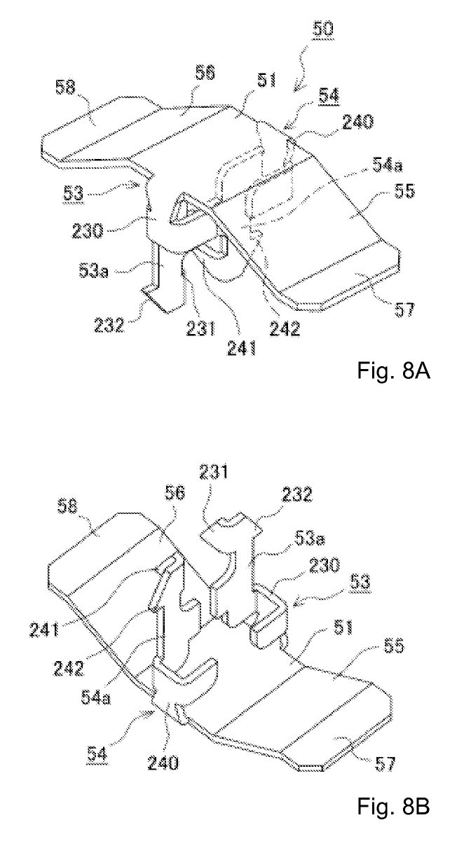

A second embodiment of the present invention is explained with reference to FIGS. 6 to 8B. The second embodiment illustrates an example in which each of the leg parts of the fixing spring includes a single leg part body.

[Configuration of Heat Sink Structure]

The heat sink structure 1 shown in FIGS. 6 to 8 is for efficiently dissipating heat generated by an electronic component and for achieving a close attachment (fixing) of the electronic component used for a circuit board of an electric device, such as a power source device, to a heat sink member. The heat sink structure 1 is configured with a fixing spring 50, a heat sink member 60, and electronic components 71, 72, 73 and 74 provided on the heat sink member 60.

The electronic components 71, 72, 73 and 74 are electronic components, such as transistors and diodes, and include the same configurations, functions and characteristics for heat as the electronic components 41 and 42. Therefore, it is necessary that bottom surfaces of the electronic components 71, 72, 73 and 74 be also closely attached to the heat sink member 60.

The fixing spring 50 includes a rectangular seat part 51 that spreads in a horizontal direction, and leg parts 53 and 53 provided so as to extend vertically downwardly (the heat sink member 60 side) at boundaries between holding parts 55 and 56 and the seat 51 and in parallel with the boundaries. In the second embodiment according to the present invention, an example is illustrated, in which the leg part 53 includes only leg part body 53a and the leg part 54 include only leg part bodies 54a.

The leg part 53 (54) is configured with a stand part 230 (240) that is connected to the seat part 51, the leg part body 53a (54a) that is connected to the stand part and that extends in a direction opposite from the seat part 51, and engagement claws 231 (241) provided at the respective tip ends of the leg part body 53a (54a).

The stand part 230 (240) is provided to extend vertically downwardly (the heat sink member 60 side) from two opposing sides (second sides) of the seat part 51. The leg part body 53a (54a) is respectively provided from the left (right) end part of the stand part 230 (240). Therefore, the leg part body 53a (54a) is offset to the left (right) from the center line of the leg part 53 (54).

Further, the leg part body 53a (54a) is provided to extend vertically downwardly (the heat sink member 60 side) from the left (right) end part of the stand part 230 (240). In addition, the leg part body 53a (54a) is formed by perpendicularly bending to a direction parallel with borderlines between the seat part 51 and holding parts 55 and 56 (a direction orthogonal to the stand parts 230 and 240).

The engagement claw 231 (241) is provided at the tip end part of the leg part body 53a (54a) and is bent in a direction orthogonal to the leg part body 53a (54a) (direction parallel with the stand parts 230 (240)). A small claw 232 (242) is provided at the leg part body 53 (54a) in a direction opposite from the engagement claw 231 (241).

The holding parts 55 and 56, the fixing parts 57 and 58, the heat sink member 60 and the engagement holes 63 and 64 have the same functions and usage as the holding parts 15 and 16, the fixing parts 17 and 18, the heat sink member 20 and the engagement holes 23 and 24 of the first embodiment.

The engagement holes 63 and 64 are provided on the heat sink member 60. The engagement claws 231 and 241 engage with edges of the engagement holes 63 and 64. Shapes and functions of the engagement holes 63 and 63 are the same as those of the engagement holes 23 and 24. In the present embodiment, an engagement claw from each of the two fixing springs 50 is inserted into, and is engaged with an engagement hole.

[Assembly Method of Heat Sink Structure]

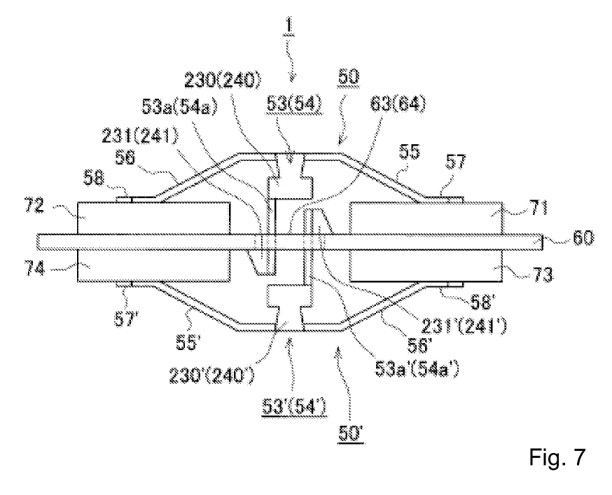

Steps for fixing electronic components by using the fixing spring 50 are explained with reference to FIGS. 6 and 7.

First, the electronic components 71 and 72 are mounted on a top surface (first heat sink surface) of the heat sink member 60. The electronic components 73 and 74 are mounted on a bottom surface (second heat sink surface) of the heat sink member 60. An insulation sheet (not shown) may be sandwiched between the heat sink member 60 and the electronic components 71 to 74.

Next, the fixing spring 50 is fitted to the heat sink member 60 from the top side. The engagement claw 231 at the tip end of the leg part 53 and the engagement claw 241 of the leg part 54 are respectively inserted into the engagement holes 63 and 64. At that time, the engagement claws 231 and 241 are inserted into the wider parts of the T-shape engagement holes 63 and 64.

Moreover, the fixing spring 50 and a fixing spring 50′, which is the same as the fixing spring 50, are inversely positioned so that the leg part bodies 53a and 54a of the fixing spring 50 and the leg part bodies 53a′ and 54a′ of the fixing spring 50′ face each other across the heat sink member 60.

Then, the fixing spring 50′ is fitted to the heat sink member 60 from the bottom side. The engagement claw 231′ at the tip end of the leg part 53′ and the engagement claw 241′ of the tip end of the leg part 54′ are respectively inserted into the engagement holes 63 and 64. At that time, the engagement claws 231′ and 241′ are inserted into the wider parts of the T-shape engagement holes 63 and 64. Therefore, the engagement claw 231 and the engagement claw 231′ as a pair are inserted into and engaged with the engagement hole 63. The engagement claw 241 and the engagement claw 241′ as a pair inserted into and engaged with the engagement hole 64.

At this time, on the top surface of the heat sink member 60, the fixing part 57 of the fixing spring 50 is positioned to contact the top surface of the electronic component 71, and the fixing part 58 is positioned to contact the top surface of the electronic component 72. On the bottom surface of the heat sink member 60, the fixing part 57′ of the fixing spring 50′ is positioned to contact the top surface of the electronic component 74, and the fixing part 58′ is positioned to contact the top surface of the electronic component 73.

Accordingly, as shown in FIG. 7, a total of four electronic components (two on each of the top and bottom surfaces of the heat sink member 60) are fixed by using two fixing springs 50.

### Third Embodiment

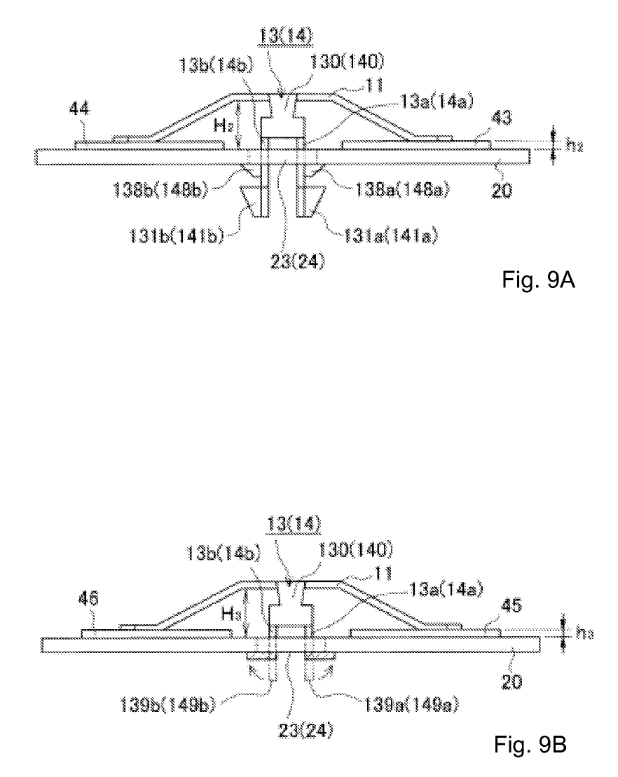

A third embodiment according to the present invention is explained using FIG. 9A. As shown in FIG. 9A, when the height h2 of electronic components 43 and 44 and the height h1 of the electronic components 41 and 42 (as shown in FIG. 4) are different, second engagement claws (third claw part) 138a and 138b (148a and 148b) may be provided at the leg part bodies 13a and 13b (14a and 14) between the stand part 130 (140) and the engagement claws 131a and 132b (141a and 141b). The second engagement claws 138a and 138b (148a and 148b) are engaged with sides of the engagement hole 23 (24). Accordingly, the electronic components 43 and 44 are fixed by adjusting the gap between the seat part 11 and the heat sink member 20 at the time of completion of assembly to H2. The third claw parts are defined as claws that are different from the engagement claws or small claws, and that are positioned between the seat part and the engagement claws. When two of the leg parts include such third claw parts each, it is preferred that all of the third claw parts are arranged at the same height along the leg bodies so that the engagement with the third claw parts is more secured.

### Fourth Embodiment

A fourth embodiment according to the present invention is explained using FIG. 9B. As shown in FIG. 9B, if the height h3 of electronic components 45 and 46 and the height h1 of the electronic components 41 and 42 (as shown in FIG. 4) are different, leg part tip end parts 139a and 139b (149a and 149b) may be provided instead of the engagement claws 131a and 131b (141a and 141b). The leg part tip end parts are made by extending the tip end of the leg part bodies 13a and 13b (14a and 14b) and are foldable.

The leg part tip end parts 139a and 139b (149a and 149b) are inserted into the engagement hole 23 (24). Then, the leg part tip end parts 139a and 139b (149a and 149b) are folded so as to conform the height h3 and engage with the engagement hole 23 (24). Accordingly, the electronic components 45 and 46 are fixed by adjusting the gap between the seat part 11 and the heat sink member 20 at the time of completion of assembly to H3. Moreover, because the folding position of the leg part front end parts 139a and 139b (149a and 149b) is arbitrarily set, electronic components are fixed with flexibility regardless of the height h3 of the electronic components 45 and 46.

Furthermore, the gap with the heat sink member 20 may be adjusted by changing a plate thickness of the heat sink member 20 around the engagement hole 23 (24) (portions where the engagement claws engage).

As illustrated in the third and fourth embodiments, positions where the fixing springs are engaged with the electronic components using the second engagement claws and the folded leg part tip end parts are defined as engagement positions.

### Another Embodiment

In addition, as another embodiment, the electronic components 41 and 42 (71, 72, 73 and 74) may be fixed by the end parts of the holding parts 15 and 16 (55 and 56) without the fixing parts 17 and 18 (57 and 58). This reduces burden associated with production, materials and the like for the fixing parts 17 and 18 (57 and 58).

As discussed above, according to the present invention, by inserting the engagement claw provided on the fixing spring into the engagement hole provided on the heat sink member, the electronic component is sandwiched and fixed to the heat sink member. Therefore, the positioning is simplified.

In addition, because the only assembly process after the positioning is the fitting of the engagement claw, there is no cracking or warping of components caused by screw-clamping.

Therefore, the assembly process and operation process are simplified, resulting in improved efficiency.

Moreover, a structure of the fixing spring is simple. Therefore, complicated manufacturing processes are not required. As a result, the manufacturing processes are simplified. This is advantageous for mass production. Further, because screws and the like are not used, the number of parts is reduced, resulting in simplified manufacturing processes.

In addition, a plurality of electronic components can be engaged with the heat sink member with a single fixing spring. The number of electronic components to be fixed to the heat sink member is adjusted by changing the number of leg parts of the fixing spring.

Furthermore, because the electronic component contacts the heat sink member and because the leg part of the fixing spring contacts the heat sink member, even if an excess pressure is accidentally applied to the fixing spring, the pressure is dispersed to the leg part and the electronic component. As a result, the excess pressure is not applied to the electronic component, resulting in prevention of damage to the electronic component.

The present disclosure may be embodied as many forms without departing from the substantive characteristics. Therefore, the above-described embodiments are merely for the explanation purpose and are not intended to limit the scope of the present invention.

What is claimed is:

1. A fixing spring for fixing an electronic component to a heat sink member that includes a flat surface on which the electronic component is disposed by inserting the fixing spring to an engagement hole disposed on the flat surface of the heat sink member, comprising:
a seat part that extends in a horizontal direction;
a holding part that is provided to extend from one of two first sides of the seat part that face each other toward the horizontal direction of the first sides and that presses the electronic component onto the heat sink member;
a leg part that is provided to extend substantially perpendicularly downwardly from one of two second sides of the seat part that face each other;
a leg part body that extends from the leg part; and
a claw part that is provided at a tip end of the leg body, wherein
the holding part biases the electronic component downwardly and thereby fixes the electronic component to the heat sink member when the claw part is engaged with the engagement hole.

2. The fixing spring according to claim 1, wherein
the first sides of the seat part are perpendicularly positioned with respect to the second sides of the seat part.

3. The fixing spring according to claim 1, wherein
a distance between the holding part and the heat sink member, which is defined where the fixing spring is fixed to the heat sink member not having the electronic component therebetween, is smaller than a height of the electronic component.

4. The fixing spring according to claim 1, wherein
the leg part provided at the seat part is comprised with first and second leg parts that are respectively arranged on the second sides of the seat part, and
the leg part body that expends from the leg part is comprised with first and second leg part bodies that are provided with each of the first and second leg parts.

5. The fixing spring according to claim 1, wherein
the leg part provided at the seat part is comprised with first and second leg parts that are respectively arranged on the second sides of the seat part, and
the leg part body is a single leg part body, being provided with each of the first and second leg parts.

6. The fixing spring according to claim 5, wherein
the claw part is provided at a tip end of the first leg part body, and another claw part is provided at a tip end of the second leg part body, thereby a pair of the claw parts is formed, and
the pair of the claw parts engages with the engagement hole.

7. The fixing spring according to claim 1, further comprising:
a fixing part that is provided at a tip end of the holding part to make a surface contact with the electronic component and to fix the electronic component.

8. The fixing spring according to claim 1, wherein
a plurality of third claw parts are provided on the leg part body, allowing an engagement position of the fixing spring and the heat sink member to vary.

9. The fixing spring according to claim 4, wherein
a third claw part is provided between the seat part and the claw part on each of the first and second leg part bodies, allowing an engagement position of the fixing spring and the heat sink member to vary.

10. The fixing spring according to claim 9, wherein
all of the third claw parts are arranged at the same height along the leg part bodies.

11. The fixing spring according to claim 1, wherein
the claw part is formed by folding the tip end part of the leg part body, and
an engagement position between the fixing spring and the heat sink member varies based on a position at which the tip end part of the leg part body is folded.

12. A fixing spring for fixing an electronic component to a heat sink member, the fixing spring comprising:
a seat part that includes a flat surface;
a pair of leg parts that extend substantially perpendicularly from second sides that face each other of the seat part, each of the leg parts including:
a stand part extending substantially perpendicularly to the flat surface of the seat part,
a leg part body provided on each of the leg parts, being substantially perpendicular to the stand part, and
a claw part provided on a tip end of the leg part body, being configured to engage with an engagement hole provided on the heat sink member; and
a holding part that extends from a first side of the seat part in a diagonal direction from the flat surface of the seat part toward the heat sink member, the first side being arranged perpendicularly to the second side of the seat part, and that is configured to press and fix the electronic component to the heat sink member by a biasing force generated by the holding part being deformed.

13. The fixing spring according to claim 12, wherein
one of the claw part protrudes in an opposite direction from the other of the claw part.

14. The fixing spring according to claim 12, wherein
the leg part bodies of the leg part are configured to in a plate shape and substantially co-planar.

15. The fixing spring according to claim 12, further comprising
each of the leg part bodies is comprised with first and second leg part bodies that extend from the leg parts, wherein
each of the claw part is comprised with first and second claw parts at the tip end of each of the first and second leg part bodies, wherein
the first claw part protrudes in a direction parallel with the second side of the seat part, and the second claw part protrudes in a direction perpendicular to the first claw part so that the first claw part and second claw part are inserted in and engage with the engagement hole, the first claw part being engaged with one edge of the engagement hole, and the second claw part being engaged with another edge of the engagement hole.

16. The fixing spring according to claim 12, wherein
the leg part bodies of the first and second leg parts are co-planar and are offset from a center line of the first and second leg parts such that the fixing spring cooperates with another fixing spring of the same configuration when the fixing spring is engaged with the heat sink member, in order to accomplish the engagement.

17. A heat sink structure comprises:
an electronic component that includes a flat surface;
a heat sink member that includes a flat surface on which the electronic component is disposed such that the flat surface of the electronic component contacts the flat surface of the heat sink member, and that includes an engagement hole of the flat surface; and
a fixing spring that is integrally formed of an elastic material so that the fixing spring generates a biasing force when being deformed, the fixing spring comprising;
a seat part that includes a flat surface;
a pair of leg parts that extend substantially perpendicularly from second sides that face each other of the seat part, each of the leg parts including:
a stand part extending substantially perpendicularly to the flat surface of the seat part,
a leg part body provided on each of the leg parts, being substantially perpendicular to the stand part, and
a claw part provided on a tip end of the leg part body, being configured to engage with an engagement hole provided on the heat sink member; and
a holding part that extends from a first side of the seat part in a diagonal direction from the flat surface of the seat part toward the heat sink member, the first side being arranged perpendicularly to the second sides of the seat part, and that is configured to press and fix the electronic component to the heat sink member by a biasing force generated by the holding part being deformed.
